(19) United States
(12) Patent Application Publication
(10) Pub. No.: US 2026/0246130 A1
(43) Pub. Date: Aug. 20, 2026

(54) SIGNAL PROCESSING CIRCUIT WITH MINIATURIZED DIMENSIONS AND REDUCED LOSS

(71) Applicant: MEDIATEK INC., Hsinchu City (TW)

(72) Inventor: Yi-Chieh Lin, Hsinchu City (TW)

(73) Assignee: MEDIATEK INC., Hsinchu City (TW)

(21) Appl. No.: 19/218,669

(22) Filed: May 27, 2025

Related U.S. Application Data
(60) Provisional application No. 63/759,223, filed on Feb. 16, 2025.

(51) Int. Cl. H01P 1/213; H01P 7/06; H03H 7/38

(52) U.S. Cl. CPC H01P 1/213; H01P 7/06; H03H 7/38

(57) ABSTRACT

A signal processing circuit includes a first signal terminal, a first conductive portion, a first matching circuit, a first combining circuit, and an output terminal. The first signal terminal is used to receive a first signal. The first conductive portion includes a first terminal coupled to the first signal terminal, and a second terminal. The first matching circuit includes a first terminal coupled to the first signal terminal, and a second terminal. The first combining circuit includes a first terminal coupled to the first signal terminal, and a second terminal. The output terminal is coupled to the second terminal of the first combining circuit, and used to output an output signal, where the output signal is generated based on at least the first signal.

### CROSS REFERENCE TO RELATED APPLICATIONS

This application claims the benefit of U.S. Provisional Application No. 63/759,223, filed on Feb. 16, 2025. The content of the application is incorporated herein by reference.

### BACKGROUND

With the continuous expansion of wireless communication and radar detection applications, corresponding demands have likewise increased. When processing wireless signals, the package dimensions of related circuits are of critical importance. A reduction in circuit size contributes to cost reduction and enhances design flexibility. For millimeter wave signal processing, impedance matching configuration presents a significant challenge for layout reduction. When developers attempt to satisfy multiple design specifications, complex trade-offs must be addressed. The simultaneous objectives of reducing layout area while minimizing insertion loss are difficult to achieve. Consequently, these challenges impede the miniaturization and performance enhancement of millimeter wave circuits.

### SUMMARY

An embodiment provides a signal processing circuit. The signal processing circuit includes a first signal terminal, a first conductive portion, a first matching circuit, a first combining circuit, and an output terminal. The first signal terminal is configured to receive a first signal. The first conductive portion comprises a first terminal coupled to the first signal terminal, and a second terminal. The first matching circuit comprises a first terminal coupled to the first signal terminal, and a second terminal. The first combining circuit comprises a first terminal coupled to the first signal terminal, and a second terminal. The output terminal is coupled to the second terminal of the first combining circuit, and configured to output an output signal, where the output signal is generated based on at least the first signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a signal processing circuit according to an embodiment.

FIG. 2 is a schematic diagram of a signal processing circuit according to another embodiment.

FIG. 3 is a schematic diagram of a signal processing circuit according to another embodiment.

FIG. 4 is a layout diagram of the signal processing circuit of FIG. 3 according to an embodiment.

FIG. 5 is a schematic diagram of a conductive portion according to an embodiment.

FIG. 6 is a schematic diagram of a conductive portion according to another embodiment.

### DETAILED DESCRIPTION

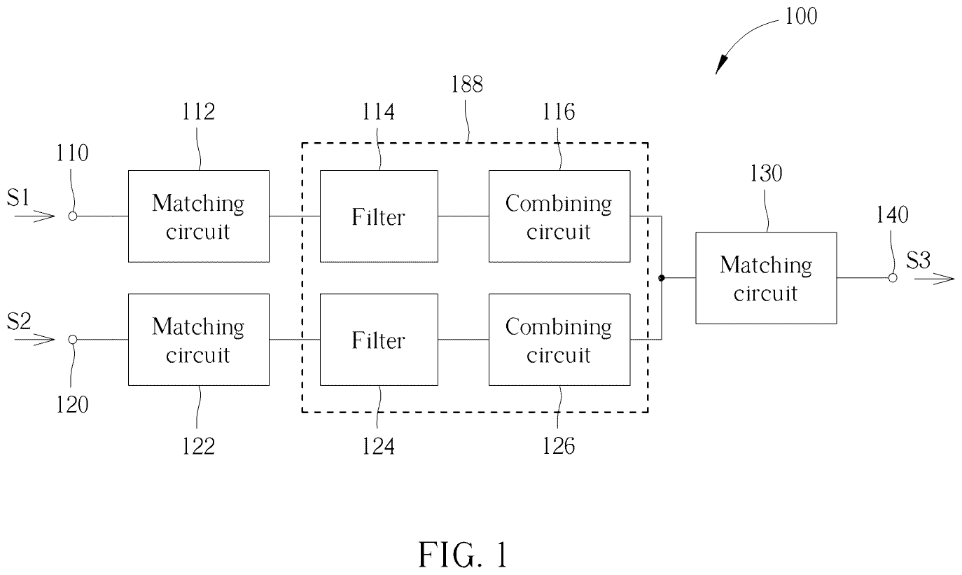

FIG. 1 is a schematic diagram of a signal processing circuit 100 according to an embodiment. The signal processing circuit 100 may include a signal terminal 110, a matching circuit 112, a filter 114, a combining circuit 116, a signal terminal 120, a matching circuit 122, a filter 124, a combining circuit 126, a matching circuit 130, and an output terminal 140. The signal terminal 110 may receive a signal S1. The signal terminal 120 may receive a signal S2. The output terminal 140 may output a signal S3, wherein the signal S3 may be generated based on the signals S1 and S2. The signals S1 and S2 belong to different frequency bands. The signals S1, S2, and S3 may be radio frequency signals. For example, the signals S1, S2, and S3 may be 5G millimeter wave signals.

The matching circuit 112, the filter 114, and the combining circuit 116 may be used to process the signal S1. The filter 114 may be a high-pass filter. The combining circuit 116 may provide high rejection for lower frequencies to attenuate signals in a lower frequency range. The length of the combining circuit 116 may be substantially 15% to 35% of the wavelength of the signal S1, for example, ¼ wavelength.

The matching circuit 122, the filter 124, and the combining circuit 126 may be used to process the signal S2. The filter 124 may be a low-pass filter. The combining circuit 126 may provide high rejection for higher frequencies to attenuate signals in a higher frequency range. The length of the combining circuit 126 may be substantially 15% to 35% of the wavelength of the signal S2, for example, ¼ wavelength.

The filter 114, the combining circuit 116, the filter 124, and the combining circuit 126 may belong to a diplexer 188. The diplexer 188 may be used to process signals of a three-terminal circuit, reduce insertion loss, and improve isolation.

As shown in the topology of the signal processing circuit 100 in FIG. 1, the signal processing circuit 100 belongs to a cascade structure. The matching circuit 112, the filter 114, and the combining circuit 116 are coupled in series. The matching circuit 122, the filter 124, and the combining circuit 126 are coupled in series.

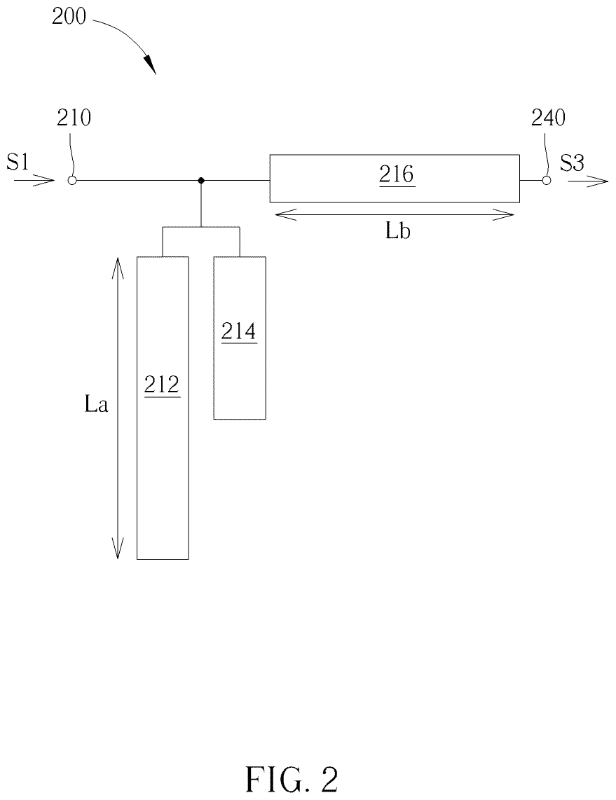

FIG. 2 is a schematic diagram of a signal processing circuit 200 according to another embodiment. The signal processing circuit 200 may include a signal terminal 210, a conductive portion 212, a matching circuit 214, a combining circuit 216, and an output terminal 240.

The conductive portion 212 may include a first terminal and a second terminal. The first terminal of the conductive portion 212 may be coupled to the signal terminal 210. The matching circuit 214 may include a first terminal and a second terminal. The first terminal of the matching circuit 214 may be coupled to the signal terminal 210. The combining circuit 216 may include a first terminal and a second terminal. The first terminal of the combining circuit 216 may be coupled to the signal terminal 210. The output terminal 240 is coupled to the second terminal of the combining circuit 216. The signal terminal 210 may receive a signal S1, and the output terminal 240 may output a signal S3. The signal S3 may be generated based on at least the signal S1.

As shown in the topology of the signal processing circuit 200 in FIG. 2, the signal processing circuit 200 is not a cascade structure. The first terminal of the conductive portion 212 and the first terminal of the matching circuit 214 may be coupled to the same node.

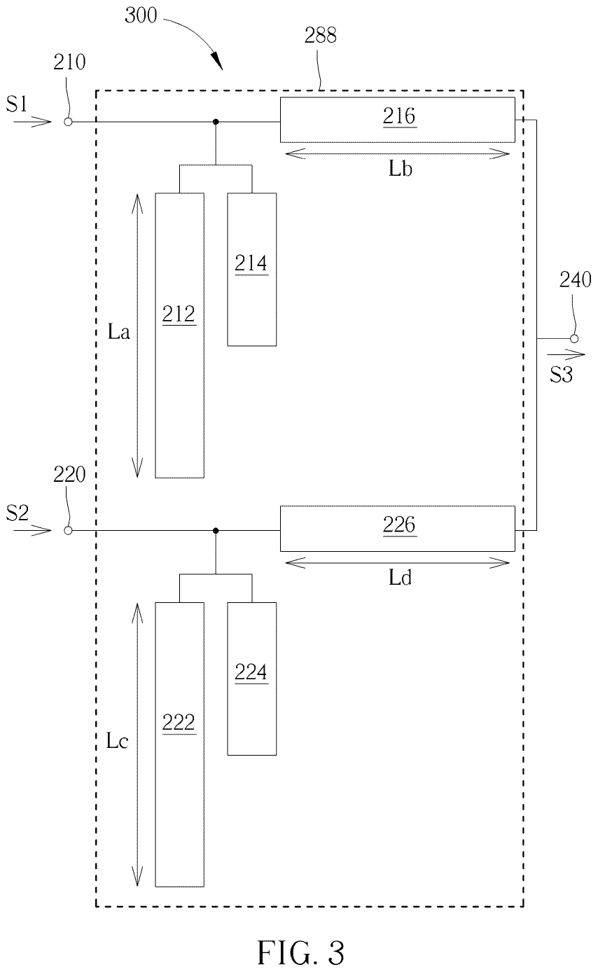

FIG. 3 is a schematic diagram of a signal processing circuit 300 according to another embodiment. The signal processing circuit 300 may include a signal terminal 210, a conductive portion 212, a matching circuit 214, a combining circuit 216, an output terminal 240, a signal terminal 220, a conductive portion 222, a matching circuit 224, and a combining circuit 226. In FIG. 3, the coupling arrangement of the signal terminal 210, the conductive portion 212, the matching circuit 214, and the combining circuit 216 is similar to that shown in FIG. 2, therefore it will not be repeated herein.

The conductive portion 212, the matching circuit 214, the conductive portion 222, and the matching circuit 224 may be formed using conductive stubs, where the lengths of the conductive stubs may be adjusted to have appropriate impedance, and the widths of the conductive stubs may be adjusted according to manufacturing processes, layout requirements, and circuit performance.

The conductive portion 212, the matching circuit 214, the combining circuit 216, the conductive portion 222, the matching circuit 224, the combining circuit 226, and the paths used for coupling may be formed using microstrip lines, or appropriate conductive materials.

The conductive portion 222 may include a first terminal and a second terminal. The first terminal of the conductive portion 222 may be coupled to the signal terminal 220. The matching circuit 224 may include a first terminal and a second terminal. The first terminal of the matching circuit 224 is coupled to the signal terminal 220. The second terminal of the matching circuit 224 may be coupled to a predetermined voltage terminal, for example, a ground terminal. The combining circuit 226 may include a first terminal and a second terminal. The first terminal of the combining circuit 226 may be coupled to the signal terminal 220. The output terminal 240 may be coupled to the second terminal of the combining circuit 216 and the second terminal of the combining circuit 226. The signal terminal 220 may receive a signal S2. The signal S3 output from the output terminal 240 may be generated based on the signal S1 and the signal S2. In FIG. 3, the signals S1 and S2 belong to different frequency bands. The signals S1, S2, and S3 may be radio frequency signals. For example, the signals S1, S2, and S3 may be 5G millimeter wave signals. The output terminal 240 may be coupled to an antenna, to output the signal S3 to the antenna.

In FIG. 3, the conductive portion 212, the matching circuit 214, the combining circuit 216, the conductive portion 222, the matching circuit 224, and the combining circuit 226 may belong to a diplexer 288. The diplexer 288 may be used to process signals of a three-terminal circuit, reduce insertion loss, and improve isolation.

The signal S1 may be corresponding to a first wavelength (denoted as wavelength λ1).

The length La of the conductive portion 212 may be corresponding to 15% to 35% of the wavelength λ1. For example, the length La may be 25% of the wavelength λ1, expressed as La=¼×λ1.

The length Lb of the combining circuit 216 may be corresponding to 15% to 35% of the wavelength λ1. For example, the length Lb may be 25% of the wavelength λ1, expressed as Lb=¼×λ1.

The signal S2 may be corresponding to a second wavelength (denoted as wavelength λ2). The length Lc of the conductive portion 222 may be corresponding to 15% to 35% of the wavelength λ2. For example, the length Lc may be 25% of the wavelength λ2, expressed as Lc=¼×λ2.

The length Ld of the combining circuit 226 may be corresponding to 15% to 35% of the wavelength λ2. For example, the length Ld may be 25% of the wavelength λ2, expressed as Ld=¼×λ2.

The conductive portion 212 may be used to perform a first high-pass filtering operation, and the combining circuit 216 may be used to perform a first low-pass filtering operation.

The conductive portion 222 may be used to perform a second low-pass filtering operation, and the combining circuit 226 may be used to perform a second high-pass filtering operation.

In the context of the present disclosure, when an element is described as having an open-circuit impedance, said element exhibits high impedance characteristics within a predetermined frequency band, thereby substantially impeding current flow through said element. This characteristic effectively inhibits signal transmission, establishing a signal blocking pathway. Conversely, when an element is described as having a short-circuit impedance, said element exhibits low impedance characteristics within a predetermined frequency band, thereby readily facilitating current flow through said element. This characteristic enables efficient signal transmission, establishing a conductive pathway.

The conductive portion 212 may have a first open-circuit impedance, and the matching circuit 216 may have a second open-circuit impedance, where the first open-circuit impedance and the second open-circuit impedance may be greater than a predetermined impedance. For example, the first open-circuit impedance and the second open-circuit impedance may be approximately infinite.

The conductive portion 222 may have a third open-circuit impedance. The matching circuit 224 may have a short-circuit impedance. The third open-circuit impedance may be greater than the short-circuit impedance. For example, the third open-circuit impedance may be approximately infinite, and the short-circuit impedance may be approximately zero.

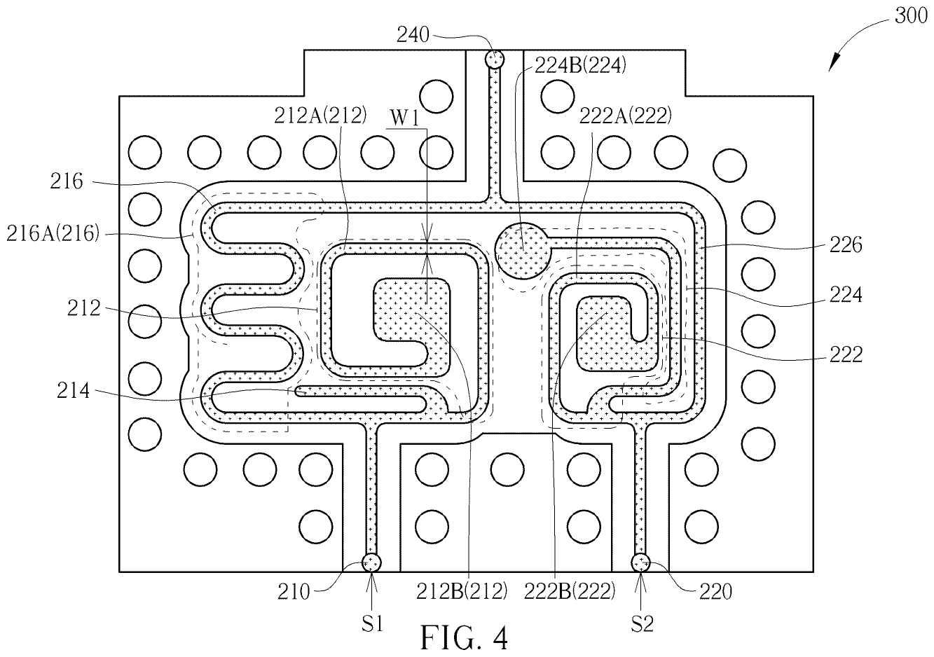

FIG. 4 is a layout diagram of the signal processing circuit 300 of FIG. 3 according to an embodiment. The conductive portion 212 may include a spiral conductor 212A and a conductive patch 212B. The spiral conductor 212A includes at least one winding turn to form a spiral shape. The spiral conductor 212A may include a first terminal and a second terminal. The first terminal of the spiral conductor 212A may be coupled to the first terminal of the conductive portion 212, to be coupled to the signal terminal 210. The conductive patch 212B may include a conductive terminal coupled to the second terminal of the spiral conductor 212A, and the second terminal of the conductive portion 212 may be located on the conductive patch 212B. That is to say, the conductive portion 212 may be formed and extended, having a fern-shaped spiral configuration, terminating at the conductive patch 212B. The spiral conductor 212A may have a width W1. Adjusting the ratio between the length and width of the spiral conductor 212A may adjust the Q value and loss value of the circuit. The Q value can represent the quality factor of a circuit, indicating the ratio of energy stored to energy dissipated, with higher Q values denoting greater frequency selectivity and potentially lower losses.

The combining circuit 216 may include a meandering conductive portion 216A. The meandering conductive portion 216A has a meandering shape and includes a first terminal and a second terminal. The first terminal of the meandering conductive portion 216A may be coupled to the first terminal of the combining circuit 216, to be coupled to the signal terminal 210. The second terminal of the meandering conductive portion 216A may be coupled to the second terminal of the combining circuit 216, to be coupled to the output terminal 240.

Similar to the conductive portion 212, the conductive portion 222 may include a spiral conductor 222A and a conductive patch 222B. The spiral conductor 222A may include at least one winding turn to form a spiral configuration. The spiral conductor 222A may include a first terminal and a second terminal. The first terminal of the spiral conductor 222A may be coupled to the first terminal of the conductive portion 222, to be coupled to the signal terminal 210. The conductive patch 222B may include a conductive terminal coupled to the second terminal of the spiral conductor 222A, and the second terminal of the conductive portion 222 may be located on the conductive patch 222B. That is to say, the conductive portion 222 may be formed and extended, having a fern-shaped spiral configuration, terminating at the conductive patch 222B.

In FIG. 4, the combining circuit 226 does not have a meandering shape, but this is merely exemplary, and embodiments are not limited thereto. If the combining circuit 226 has a meandering conductive portion, it also falls within the scope of embodiments.

In FIG. 4, the second terminal 224B of the matching circuit 224 may be coupled to a predetermined voltage terminal, for example, a ground terminal. In FIG. 4, the frequency of the signal S1 may be higher than the frequency of the signal S2. For example, the signal S1 may have a frequency of 39 GHz, and the signal S2 may have a frequency of 28 GHz, embodiments are not limited thereto.

In FIG. 4, the signal terminal 210, the conductive portion 212, the matching circuit 214, the combining circuit 216, the output terminal 240, the signal terminal 220, the conductive portion 222, the matching circuit 224, and the combining circuit 226 may be formed using a conductive layer, such as a metal layer. Other portions may be formed using an insulating layer. The signal processing circuit 300 may be formed on a circuit board, or may be formed using a semiconductor manufacturing process.

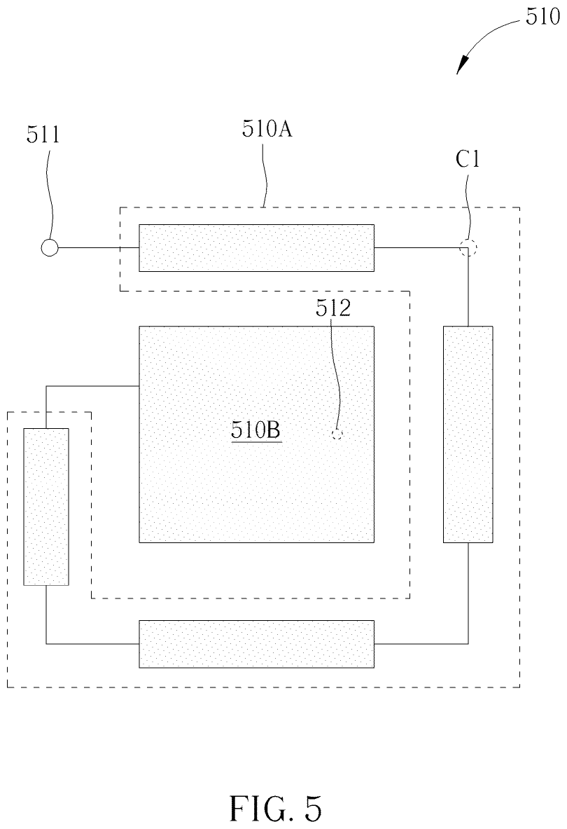

FIG. 5 is a schematic diagram of a conductive portion 510 according to an embodiment. The conductive portion 510 may be used to form the conductive portions 212 and 222 as described above. The conductive portion 510 may include a first terminal 511 and a second terminal 512. The first terminal 511 may be coupled to a signal terminal (such as the signal terminal 210 or 220 described above) to receive a radio frequency signal. The conductive portion 510 may include a spiral conductor 510A. The spiral conductor 510A may include at least one winding turn to form a fern-shaped resonator.

In FIG. 5, the spiral conductor 510A has a turning angle C1. However, this is merely exemplary, and the winding turns of the spiral conductor 520A may also approximate a circular shape, an elliptical shape, or a more rounded shape without turning angles. In FIG. 5, the spiral conductor 520A rotates clockwise. However, this is merely exemplary, and if a counterclockwise rotating layout is adopted to form the spiral conductor, it also falls within the scope of the embodiments.

The spiral conductor 510A may be coupled to a conductive patch 510B. The second terminal 512 of the conductive portion 510 may be located on the conductive patch 510B. In FIG. 5, the conductive patch 510B is square, but this is merely exemplary. The conductive patch 510B may also have a rectangular, circular, elliptical, triangular, polygonal, rounded rectangular, or predetermined shape. The required shape may be adjusted according to layout requirements and actual performance. The conductive patch 520B may not be coupled to a predetermined voltage terminal (such as a ground terminal), to have an open-circuit impedance.

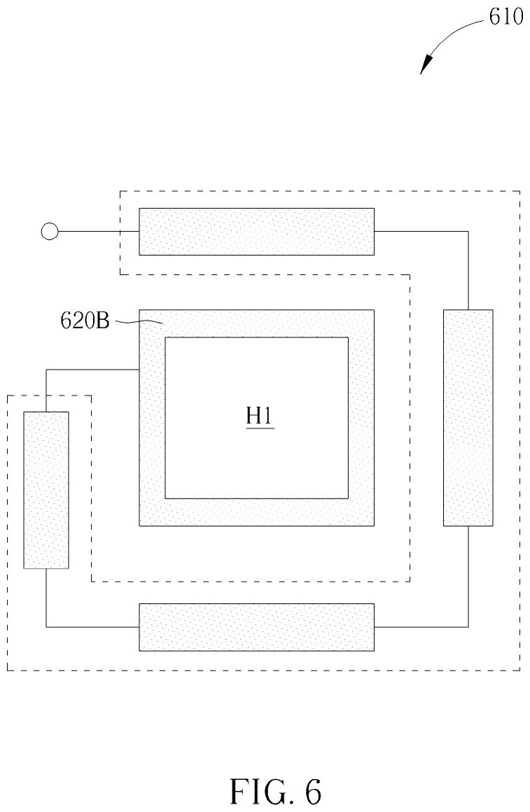

FIG. 6 is a schematic diagram of a conductive portion 610 according to another embodiment. The conductive portion 610 may be used to form the conductive portions 212 and 222 as described above. The similarities between the conductive portion 610 and the conductive portion 510 are not reiterated. Unlike the conductive portion 510, the conductive patch 620B of the conductive portion 610 may have a hole H1. When operating at a higher frequency band, the loss may be reduced because of the hole H1. The shape of the hole H1 may be rectangular, circular, elliptical, triangular, polygonal, rounded rectangular, or a predetermined shape. The shape of the hole H1 may be adjusted according to layout requirements and actual performance.

FIG. 5 and FIG. 6 illustrate spiral resonant cavity structures with varying line-widths along their paths. However, embodiments are not limited thereto, and implementations with uniform line-width also fall within the scope of the embodiments. The line-width of the path may be determined based on circuit performance requirements and manufacturing process limitations.

In summary, the signal processing circuits 200 and 300 enable a significant enhancement in circuit compactness. For example, by using the signal processing circuit 300, the circuit size can be reduced from 0.368 mm² to 0.22 mm². The conductive portions 212, 222, 510, and 610 described herein, which incorporate spiral conductors, function as resonators exhibiting a fern-shaped configuration. The implementation of fern-shaped conductive portions and/or meandering combining circuits within signal processing devices facilitates enhanced performance characteristics. Such configurations enable the reduction of circuit area, improvement of Q value, minimization of insertion losses, and provision of sufficient isolation parameters. The aforementioned technical solutions can be advantageously employed in the implementation of diplexers for processing high-frequency signals, specifically 5G millimeter wave radio frequency signals.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal processing circuit, comprising:
a first signal terminal, configured to receive a first signal;
a first conductive portion, comprising a first terminal coupled to the first signal terminal, and a second terminal;
a first matching circuit, comprising a first terminal coupled to the first signal terminal, and a second terminal;
a first combining circuit, comprising a first terminal coupled to the first signal terminal, and a second terminal; and
an output terminal, coupled to the second terminal of the first combining circuit, configured to output an output signal, wherein the output signal is generated based on at least the first signal.

2. The signal processing circuit of claim 1, wherein the first signal is corresponding to a first wavelength, and a length of the first conductive portion is corresponding to 15% to 35% of the first wavelength.

3. The signal processing circuit of claim 1, wherein the first signal is corresponding to a first wavelength, and a length of the first combining circuit is corresponding to 15% to 35% of the first wavelength.

4. The signal processing circuit of claim 1, wherein the first conductive portion comprises:
a spiral conductor, comprising at least one winding turn, the spiral conductor comprising a first terminal coupled to the first terminal of the first conductive portion, and a second terminal; and
a conductive patch, comprising a conductive terminal coupled to the second terminal of the spiral conductor, wherein the second terminal of the first conductive portion is located on the conductive patch.

5. The signal processing circuit of claim 4, wherein the conductive patch has a shape of a rectangle, a circle, an ellipse, a triangle, a polygon, a rounded rectangle, or a predetermined shape.

6. The signal processing circuit of claim 4, wherein the conductive patch has a hole.

7. The signal processing circuit of claim 1, wherein:
the first combining circuit comprises a meandering conductive portion; and
the meandering conductive portion comprises a first terminal coupled to the first terminal of the first combining circuit, and a second terminal coupled to the second terminal of the first combining circuit.

8. The signal processing circuit of claim 1, wherein the first conductive portion has a first open-circuit impedance, the first matching circuit has a second open-circuit impedance, and the first open-circuit impedance and the second open-circuit impedance are greater than a predetermined impedance.

9. The signal processing circuit of claim 8, wherein the first open-circuit impedance and the second open-circuit impedance are approximately infinite.

10. The signal processing circuit of claim 1, further comprising:
a second signal terminal, configured to receive a second signal;
a second conductive portion, comprising a first terminal coupled to the second signal terminal, and a second terminal;
a second matching circuit, comprising a first terminal coupled to the second signal terminal, and a second terminal; and
a second combining circuit, comprising a first terminal coupled to the second signal terminal, and a second terminal coupled to the output terminal;
wherein the output signal is generated based on the first signal and the second signal, and the first signal and the second signal are corresponding to two different frequency bands.

11. The signal processing circuit of claim 10, wherein the second signal is corresponding to a second wavelength, and a length of the second conductive portion is corresponding to 15% to 35% of the second wavelength.

12. The signal processing circuit of claim 10, wherein the second signal is corresponding to a second wavelength, and a length of the second combining circuit is corresponding to 15% to 35% of the second wavelength.

13. The signal processing circuit of claim 10, wherein the first conductive portion is configured to perform a first high-pass filtering operation, and the first combining circuit is configured to perform a first low-pass filtering operation.

14. The signal processing circuit of claim 13, wherein the second conductive portion is configured to perform a second low-pass filtering operation, and the second combining circuit is configured to perform a second high-pass filtering operation.

15. The signal processing circuit of claim 10, wherein the second conductive portion has a third open-circuit impedance, the second matching circuit has a short-circuit impedance, and the third open-circuit impedance is greater than the short-circuit impedance.

16. The signal processing circuit of claim 15, wherein the third open-circuit impedance is approximately infinite, and the short-circuit impedance is approximately zero.

17. The signal processing circuit of claim 10, wherein:
the second terminal of the second matching circuit is coupled to a predetermined voltage terminal.

18. The signal processing circuit of claim 10, wherein the second conductive portion comprises:
a spiral conductor, comprising at least one winding turn, the spiral conductor comprising a first terminal coupled to the first terminal of the second conductive portion, and a second terminal; and
a conductive patch, comprising a conductive terminal coupled to the second terminal of the spiral conductor, wherein the second terminal of the second conductive portion is located on the conductive patch.

19. The signal processing circuit of claim 18, wherein the conductive patch has a shape of a rectangle, a circle, an ellipse, a triangle, a polygon, a rounded rectangle, or a predetermined shape.

20. The signal processing circuit of claim 18, wherein the conductive patch has a hole.
